(19) United States
(12) Patent Application Publication
(10) Pub. No.: US 2014/0317913 A1
(43) Pub. Date: Oct. 30, 2014

(54) LIFTING APPARATUS FOR PRINTED CIRCUIT BOARD

(71) Applicants: Hon Hai Precision Industry Co., Ltd., New Taipei (TW); Hong Fu Jin Precision Industry (ShenZhen) Co., Ltd., Shenzhen (CN)

(72) Inventor: WEN-HU LU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/133,927

(22) Filed: Dec. 19, 2013

(30) Foreign Application Priority Data
Apr. 30, 2013 (CN) 2013101552599

(51) Int. Cl. H05K 13/04

(52) U.S. Cl. CPC H05K 13/0404
USPC 29/762

(57) ABSTRACT

A lifting apparatus for a printed circuit board includes a first handle and a second handle. The first handle is secured adjacent a first edge of the printed circuit board. The first handle includes a main body and a pair of mounting pieces. The pair of mounting pieces is secured on the printed circuit board. The main body is slidably mounted on the pair of mounting pieces. The second handle is secured adjacent a second edge of the printed circuit board which is opposite to the first edge.

### BACKGROUND

1. Technical Field

The disclosure generally relates to lifting apparatuses, and more particularly to a lifting apparatus for lifting a printed circuit board.

2. Description of Related Art

In a server system, there are a number of printed circuit boards for mounting a number of electronic components. Usually, the printed circuit boards are mounted in a narrow space. Because the narrowness of the space, it may be inconvenient to move the printed circuit boards.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a lifting apparatus for a printed circuit board, which includes a first handle and a second handle.

FIG. 2 is an exploded, isometric view of the first handle of FIG. 1.

FIG. 3 is an assembled view of the first handle of FIG. 2.

FIG. 4 is an assembled view of the lifting apparatus of FIG. 1.

FIG. 5 is another assembled view of the lifting apparatus of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

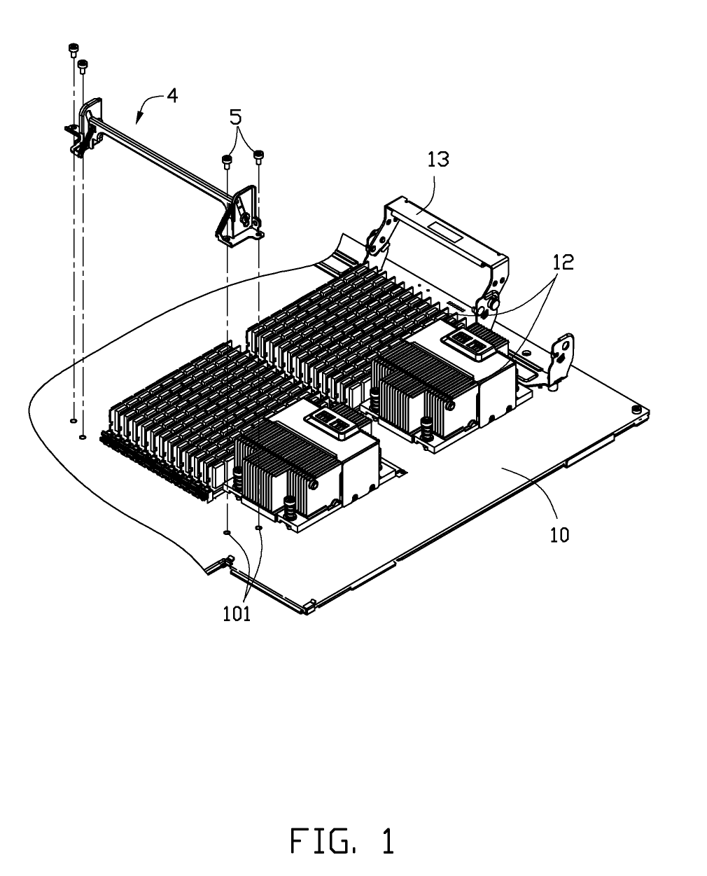

FIG. 1 shows one embodiment of a lifting apparatus for lifting a printed circuit board 10. The lifting apparatus includes a first handle 4 and a second handle 13. The first handle 4 and the second handle 13 can be mounted on opposite edges of the printed circuit board 10.

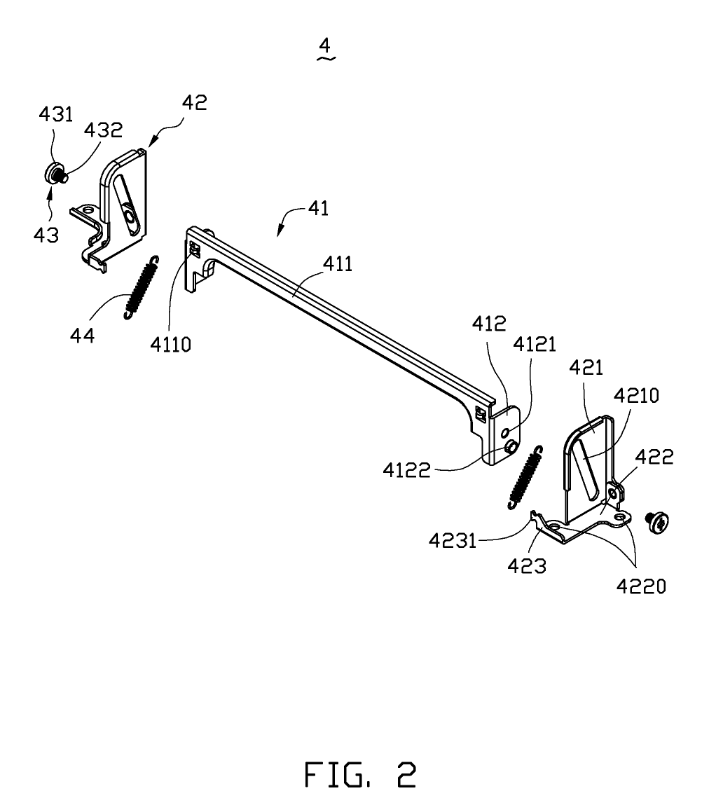

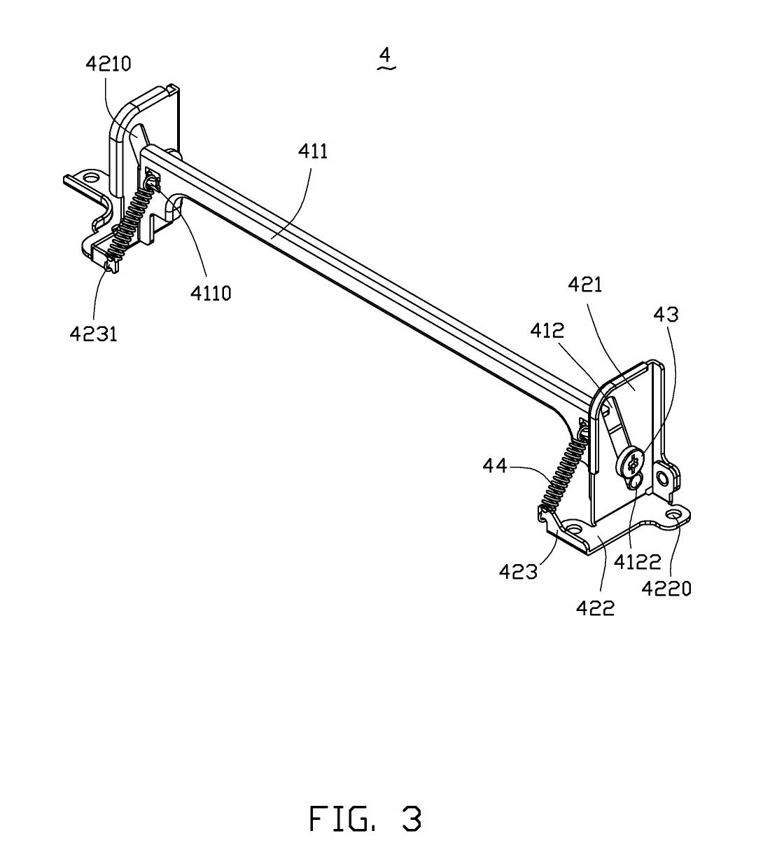

FIGS. 2 and 3 show that the first handle 4 includes a main body 41 and a pair of mounting pieces 42. The main body 41 includes a beam 411 and a pair of connecting pieces 412 connected to opposite ends of the beam 411. The beam 411 forms a first clasp 4110 adjacent to each of the connecting pieces 412. Each of the connecting piece 412 defines a connecting hole 4121 and forms a post 4122. The post 4122 is located below the connecting hole 4121. A connection line between the post 4122 and the connecting hole 4121 extends aslant.

Each of the mounting piece 42 includes a base 422 and a supporting piece 421 perpendicularly connected to the base 422. The supporting piece 421 is substantially parallel to the connecting piece 412 of the main body 41. The supporting piece 421 defines a sliding groove 4210 which extends in a same direction as the connection line between the post 4122 and the connecting hole 4121. A width of the sliding groove 4210 is substantially equal to a diameter of the post 4122. The base 422 includes a flange 423. A second clasp 4231 is formed on the flange 423. The base 422 defines a plurality of through holes 4220.

The first handle 4 further includes two sliding members 43 and two springs 44. The sliding member 43 includes a head portion 431 and a pole portion 432 connected to the head portion 431. A diameter of the head portion 431 is larger than the width of the sliding groove 4210, and a diameter of the pole portion 432 is smaller than the width of the sliding groove 4210.

FIG. 1 shows that the printed circuit board 10 defines a plurality of mounting holes 101 corresponding to the plurality of through holes 4220 of the first handle 41.

FIGS. 2 and 3 show that to assemble the first handle 4, the post 4122 and the connecting hole 4121 of the main body 41 are aligned to the sliding groove 4210. The post 4122 is inserted in the sliding groove 4210. The pole portion 432 of the sliding member 43 is inserted in the sliding groove 4210 and secured in the connecting hole 4121 of the main body 41. Thereby, the main body 41 can move in respect to the mounting piece 42 with the post 4122 and the pole portion 432 sliding in the sliding groove 4210. One end of the spring 44 is secured on the first clasp 4110 of the main body 41, and another end of the spring 44 is secured on the second clasp 4231. When the pole portion 432 abuts a bottom edge of the sliding groove 4210, the spring 44 is slightly extended.

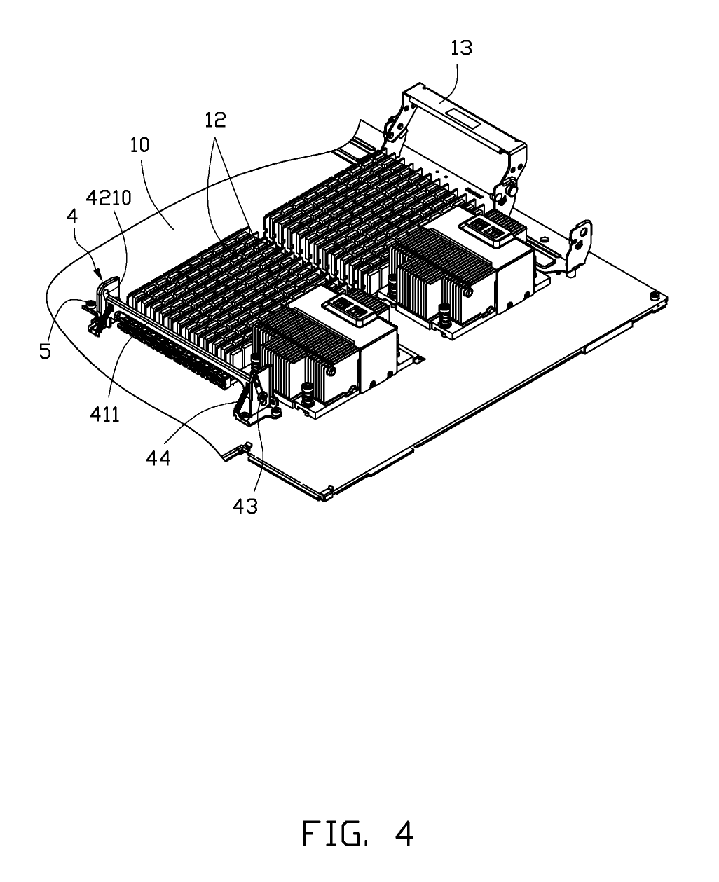

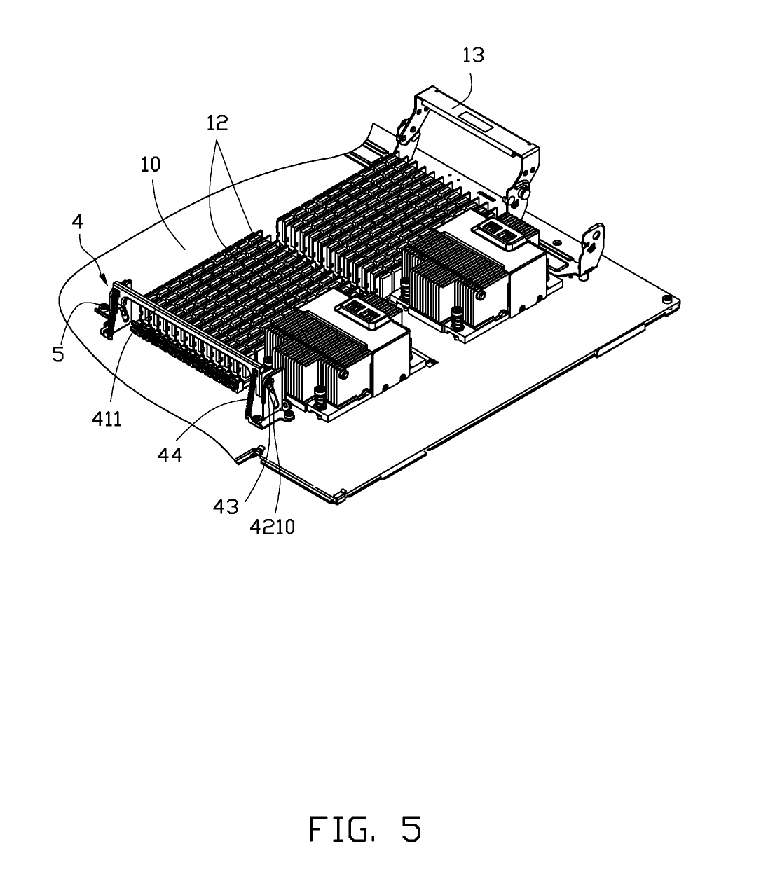

FIGS. 4 and 5 show that to mount the first handle 4 on the printed circuit board 10, the plurality of through holes 4220 of the first handle 4 is aligned to the plurality of mounting holes 101 of the printed circuit board 10, and a plurality of fasteners 5 are secured in the plurality of through holes 4220 and the plurality of mounting holes 101. The second handle 30 is mounted on the printed circuit board 10 in conventional manners, such as screws, or rivets, for example.

To move the printed circuit board 10, the main body 41 of the first handle 4 is pulled. The post 4122 and the pole portion 432 of the sliding member 43 slides upwardly in the sliding groove 4210 until the post 4122 abuts a top edge of the sliding groove 4210. At this position, the first handle 4 is lifted up, and the spring 44 is elastically extended. Thereby, the printed circuit board 10 can be moved by the first handle 4 and the second handle 30. Further, the main body 41 can move back to its original position by rebounding of the spring 44 when the main body 41 of first handle 4 is released.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A lifting apparatus for a printed circuit board, comprising:
a first handle configured to secure to a first edge of a printed circuit board, the first handle comprising a main body and a pair of mounting pieces, the pair of mounting pieces being configured to secure on the printed circuit board, and the main body being slidably mounted on each of the pair of mounting pieces; and
a second handle configured to secure to a second edge of the printed circuit board which is opposite to the first edge.

2. The lifting apparatus of claim 1, wherein each of a pair of connecting pieces is connected to each opposite ends of the main body, each of the pair of connecting pieces comprises a post, each of the mounting piece defines a sliding groove, and the post is configured to slide in the sliding groove.

3. The lifting apparatus of claim 2, wherein each of the pair of connecting pieces defines a connecting hole, a sliding member is inserted into the sliding groove and mounted in the connecting hole.

4. The lifting apparatus of claim 3, wherein the sliding groove extends in a same direction as a connection line between the post and the connecting hole.

5. The lifting apparatus of claim 3, wherein the sliding member comprises a head portion and a pole portion, a diameter of the head portion is larger than the width of the sliding groove, a diameter of the pole portion is smaller than the width of the sliding groove, and the pole portion is configured to slide in the sliding groove.

6. The lifting apparatus of claim 2, wherein each of the mounting pieces comprises a base and a supporting piece, the supporting piece is configured to secure to the printed circuit board, and the supporting piece is parallel to the connecting piece.

7. The lifting apparatus of claim 1, wherein the main body comprise a pair of first clasps, each of the pair of mounting pieces comprises a second clasp, and each of a pair of springs is secured between each of the pair of first clasps and the second clasps.

8. A lifting apparatus for a printed circuit board, comprising:
a first handle configured to secure to a first edge of a printed circuit board, the first handle comprising a main body and a mounting piece, the mounting piece being configured to secure on the printed circuit board, the main body being slidably mounted on the mounting piece, a spring attached between the main body and the mounting piece, and the spring being elastically deformed when the main body is moved with respect to the mounting piece; and
a second handle configured to secure to a second edge of the printed circuit board which is opposite to the first edge.

9. The lifting apparatus of claim 8, wherein a connecting piece is connected to an end of the main body, the connecting piece comprises a post, the mounting piece defines a sliding groove, and the post is configured to slide in the sliding groove.

10. The lifting apparatus of claim 9, wherein the connecting piece defines a connecting hole, a sliding member is inserted into the sliding groove and mounted in the connecting hole.

11. The lifting apparatus of claim 10, wherein the sliding groove extends in a same direction as a connection line between the post and the connecting hole.

12. The lifting apparatus of claim 10, wherein the sliding member comprises a head portion and a pole portion, a diameter of the head portion is larger than the width of the sliding groove, a diameter of the pole portion is smaller than the width of the sliding groove, and the pole portion is adapted to slide in the sliding groove.

13. The lifting apparatus of claim 9, wherein the mounting piece comprises a base and a supporting piece, the supporting piece is configured to secure to the printed circuit board, and the supporting piece is parallel to the connecting piece.

14. The lifting apparatus of claim 8, wherein the main body comprises a first clasp, the mounting pieces comprises a second clasp, and the spring is secured between the first clasps and the second clasps.
